(19) United States
(12) Patent Application Publication
(10) Pub. No.: US 2026/0312578 A1
(43) Pub. Date: Oct. 8, 2026

(54) RADIO FREQUENCY TRANSISTOR SWITCH CONFIGURATION

(71) Applicant: GlobalFoundries U.S. Inc., Malta, NY (US)

(72) Inventors: ABDELLATIF BELLAOUAR, Richardson, TX (US); ARUL BALASUBRAMANIYAN, Plano, TX (US); SHAFIULLAH SYED, Murphy, TX (US)

(21) Appl. No.: 19/173,346

(22) Filed: Apr. 8, 2025

(51) Int. Cl. H03K 17/06

(52) U.S. Cl. CPC H03K 17/063

(57) ABSTRACT

An RF switching circuit and method. The circuit includes a FDSOI RVT FET that has an N-well and a P-well. The circuit receives a signal indicating an on state or an off state. A bias voltage source provides a high N-well voltage to the N-well and provides, based on the signal indicating the on state, a high P-well bias voltage to the P-well, were the high N-well voltage and the high P-well voltage are higher than a supply voltages supplied to any of the source, gate, or drain of the FDSOI RVT FET. A low P-well voltage is provided to the P-well based on the switch control signal indicating the off state, where the low P-well voltage facilitates the FDSOI RVT FET switching to an off state.

### BACKGROUND

### Field

This invention relates generally to solid-state circuits that control switching of analog signals, and more specifically to transistor switching circuit configurations.

### Related Art

Radio Frequency (RF) circuits include elements, referred to herein as RF switches, that electrically switch, i.e., selectively convey or block, RF signals based on switching control inputs. In some examples, such as to accommodate higher RF power levels, RF switches include a number of series connected transistors that selectively connect an RF input to an RF output. An arrangement of such series connected transistors is referred to herein as a stacked switch configuration. A switch control signal is able to indicate that the RF switch is to be placed into an on state in which the series connected transistors conduct RF energy from the RF input to the RF output. The switching control signal is also able to indicate that the RF switch is to be placed into an off state where each transistor provides an amount of isolation of the RF signal such that a combination of the isolation provided by each transistor is provided between the RF input and the RF output.

In some applications, RF switches are specified to operate in an on state at relatively high power levels while also complying with linearity specifications that limit, for example, the amount of energy that can be produced at harmonic frequencies. A level of linearity to comply with the harmonic level limit imposed by such applications in conventional designs often leads to tradeoffs that include, for example, increased total circuit costs or reduced integration capabilities.

### BRIEF DESCRIPTION OF THE DRAWINGS

The present invention is illustrated by way of example and is not limited by the accompanying figures, in which like references indicate similar elements. Elements in the figures illustrated for simplicity and clarity and have not necessarily been drawn to scale.

FIG. 1 illustrates a triple well, Fully Depleted Silicon On Insulator (FDSOI) regular threshold voltage (RVT) Field Effect Transistor (FET) cross section, according to an example.

FIG. 2 illustrates a stacked switch circuit arrangement, according to an example.

FIG. 3 illustrates a multiplexed RF switching arrangement, according to an example.

FIG. 4 illustrates a bias voltage multiplexer circuit, according to an example.

FIG. 5 illustrates an ith bias voltage multiplexer circuit, according to an example.

FIG. 6 illustrates a dual bias voltage multiplexer, according to an example.

### DETAILED DESCRIPTION

The below described systems and methods describe a Radio Frequency (RF) on-off switch circuit that uses Fully Depleted Silicon On Insulator (FDSOI) regular threshold voltage (RVT) Field Effect Transistors (FETs) formed on a substrate with standard substrate resistivity and includes a high voltage generation and high voltage bias switching configuration to provide cost effective, RF switching circuits with improved linearity. In some examples, an RF switching circuit configuration has a stacked configuration of triple well FDSOI RVT FETs. Such RF switching circuits in some examples also includes a high voltage generation circuit to provide high voltage bias voltages to a back gate, e.g., a P-well, and to an N-well layer of the triple well FDSOI RVT FET when those transistors are in an “on” or conducting state. Applying a high voltage bias voltage to the P-well and N-well layers of a triple well FDSOI FET, or transistor, while the transistor is conducting RF energy has been found to advantageously increase the “on” state linearity of the transistor and thus reduce harmonic generation. In order to effectively turn off the triple well transistor, a lower bias voltage is applied to at least the P-well, and in some examples also to the N-well, when the triple well transistor is in the “off” state. In some examples, the N-well is Alternating Current (AC) floated. A high voltage multiplexer circuit is provided to selectively provide the high voltage bias voltages to the P-well, and N-well in some examples, of triple well transistors in each switch in order to facilitate fabrication of RF switches that are able to be independently switched on and off. In some examples, a number of such triple well FDSOI RVT FETs are arranged in a stacked switch circuit in order to provide desired isolation when in an “off” state.

The below described systems and methods that apply a high bias voltages to the P-well and to the N-well when in the on state advantageously allow the use of FDSOI RVT FETs with standard substrate resistivity to switch RF signals with high linearity to result in lower harmonic signal generation when the switch is in its on or conducting state. The belowdescribed systems and methods are able to obviate the use RF switches that include transistors formed with high substrate resistivity by allowing circuits to use FDSOI RVT transistors with standard substrate resistivity that allow realizing more complete circuits using the same fabrication technology and thus advantageously allow for higher levels of integration. For example, realizing such RF switches using FDSOI technology facilitates integration of switch modules onto a single substrate as opposed to conventional designs that construct such RF switches with very high resistivity substrates, which generally introduces higher costs requires additional assembly complexity.

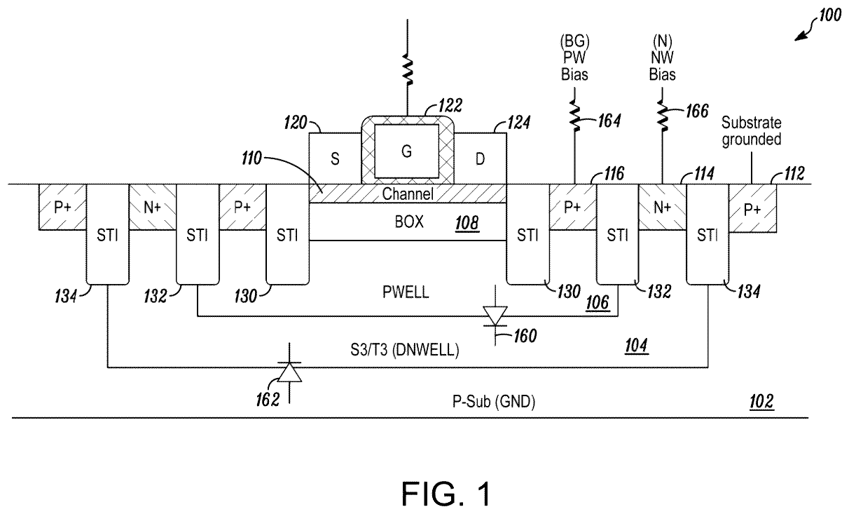

FIG. 1 illustrates a triple well FDSOI RVT FET cross section 100, according to an example. The triple well FDSOI RVT FET cross section 100 depicts an example of a cross section of a transistor that is used in a stacked transistor RF switch circuit of the presently described systems and methods.

The triple well FDSOI RVT FET cross section 100 depicts a P-doped or P-type global substrate 102. In operations, the P-type global substrate 102, which is able to extend to other semiconductor devices fabricated thereon, is held at a ground voltage potential via a ground connection to a substrate terminal 112. The triple well FDSOI RVT FET cross section 100 depicts a source 120, a gate 122 and a drain 124 on a first side of a channel 110. A Burried OXide (BOX) layer 108 is formed beneath the channel 110 with a first side of the BOX layer 108 adjacent to a second side of the channel 110 that is opposite the first side of the channel 110.

A back-gate region is formed as a P-doped region or p-doped well, referred to as a P-well 106, beneath the BOX layer 108. A first side of the P-well 106 is adjacent to the second side of the BOX layer 108. A deep N-doped well, referred to herein as an N-well 104, is formed beneath the P-well 106 adjacent to a second side of the P-well 106 that is opposite the first side of the P-well 106. The P-well 106 has a P-well terminal 116 that provides an electrical terminal for connection to the P-well 106. The N-well 104 has an N-well terminal 114 that provides an electrical connection to the N-well 104. The P-well terminal 116 is connected to a back gate bias voltage through a back gate resistor 164 and the N-well terminal 114 is connected to an N-well bias voltage through an N-well bias voltage resistor 166.

The P-N junction between the P-well 106 and the N-well 104, as is depicted by a first diode symbol 160, provides isolation between the P-well 106 and N-well 104 based on the P-well bias voltage and N-well bias voltage that are applied to those wells via the P-well terminal 116 and the N-well terminal 114, respectively. The P-N junction between the P-type global substrate 102 and the N-well 104, as is depicted by a second diode symbol 162, provides isolation between the P-type global substrate 102 and the N-well 104 based on the positive N-well bias voltage that is applied to the N-well 104 via the N-well terminal 114.

A first Shallow Trench Isolation (STI) region 130 is formed adjacent to the channel 110 and BOX layer 108 and extends into the top of the P-well region 106. A second STI region 134 is formed between the P-well 106 and the N-well 104. A third STI region 136 is formed between the N-well region and the P-type global substrate 102. The first STI region 130, the second STI region 132 and the third STI region 134 are filled with an insulating material.

In an example, an FDSOI RVT FET includes a gate structure 122, a channel 110 having a channel first side adjacent the gate structure and a channel second side that is opposite the channel first side, a buried oxide layer 108 having a buried oxide layer first side adjacent to the channel second side, and a buried oxide layer second side that is opposite the buried oxide layer first side, a P-dopped well (P-well) 106 having a P-well first side adjacent to the buried oxide layer second side, and a P-well second side opposite the P-well first side, and an N-dopped well (N-well) 104 adjacent to the p-well second side.

It has been observed that providing a high voltage bias to the back gate or P-well region 106, such as via the P-well terminal 116, relative to the ground potential and voltages present on the gate 122, source 120 or drain 124 reduces the resistance of the channel 110 when the channel 110 is conducting and thus the transistor is in an on state. A high voltage applied to the P-well region 106, however, affects the off state characteristic of the transistor and thus is able to reduce isolation from the source 120 to the drain 124 when the transistor is in the off state. In order to improve the operation of the triple well FDSOI RVT FET in both its on and off states, the bias voltage applied to the P-well 106 depends on the state of the transistor. When the transistor is in the on state, a high bias voltage is applied to the P-well 106 and when the transistor is in an off state, a lower bias voltage is applied to the P-well 106.

It has also been observed that applying a high bias voltage to the N-well 104 decreases the capacitance from the source 120 and drain 124 to the global substrate 102 when the transistor is in the on state. In general, the bias voltage applied to the N-well 104 is higher than the bias voltage applied to the P-well 106 in order to maintain a reverse bias on the PN junction formed between the P-well 106 and N-well 104 as symbolized by the first diode symbol 160.

In the present discussion, a high bias voltage refers to a voltage that is higher than other voltages present in a circuit incorporating the triple well FDSOI RVT FET. In an example, such a circuit has a core voltage in the vicinity of 0.8 volts (V) and an Input/Output (I/O) voltage of 1.8 V. In such an example, a high voltage applied as bias voltages to the P-well, N-well, or both, are voltages greater than the 1.8 V that is the higher of the core voltage or I/O voltage of its circuit. In an example, high voltages applied as bias voltages to the P-well, N-well, or both, are greater than supply voltages provided to any of the source 120, the gate 122, or the drain 124.

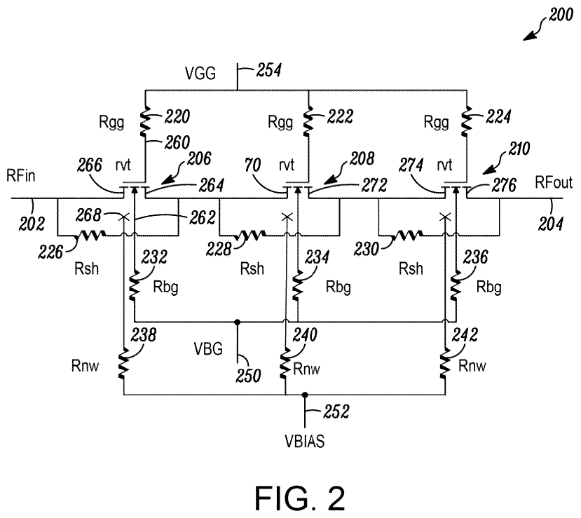

FIG. 2 illustrates a stacked switch circuit arrangement 200, according to an example. The stacked switch circuit arrangement 200 is an example of a radio frequency switching transistor circuit that has an RF input 202 that receives an RF signal and an RF output 204 that is able to produce the RF signal received via the RF input 202 when the stacked switch circuit arrangement 200 is in an on condition. When the stacked switch circuit arrangement 200 is in an off state, RF isolation is provided between the RF input 202 and RF output 204. Control of the stacked switch circuit arrangement 200 to change between its off state and on state is achieved by changing various voltage configurations as is described below. In some examples, the stacked switch circuit arrangement operating with FDSOI RVT FETs as described herein is suitable to switch RF signals with RF frequencies that fall within a range between six gigahertz (6 GHz) and nine gigahertz (9 GHz).

The stacked switch circuit arrangement 200 includes three transistors, a first transistor 206, a second transistor 208 and a third transistor 210, that are arranged in a series, or stacked, configuration. Each of these three transistors in an example is a triple well, FDSOI RVT FET. An example of a triple well, FDSOI RVT FET as is used in the stacked switch circuit arrangement 200, is described in further detail above with regards to the triple well, FDSOI RVT FET cross section 100.

The stacked switch circuit arrangement 200 has a gate voltage (VGG) input 254 that provides a gate voltage to the gates of the three FDSOI RVT FETs through separate gate resistors Rgg including a first Rgg 220, a second Rgg 222 and a third Rgg 224. The VGG input 254 receives a voltage level based on whether the FDSOI RVT FET is to be in an on state or an off state. The stacked switch circuit arrangement 200 also has a back-gate voltage (VBG) terminal 250 that provides a back-gate voltage the back-gate terminal of the three transistors through separate back-gate resistors Rbg including a first Rbg 232, a second Rbg 234 and a third Rbg 236. A bias voltage (VBIAS) terminal 252 provides an N-well bias voltage to the N-well terminal of the three transistors through separate N-well resistors Rnw including a first Rnw 238, a second Rnw 240 and a third Rnw 242.

Using the first transistor 206 as an example, a first gate 260 of the first transistor 206 is connected to the VGG input 254 via the first Rgg 220, a first back gate connection 262 is connected to the VBG terminal 250 through the first Rbg 232, and a first N-Well connection 268 is connected to the VBIAS terminal 252 through the first Rnw 238. The respective terminals of the second transistor 208 and third transistor 210 are similarly connected to the VGG input 254, the VBG terminal 250, and the VBIAS terminal 252 via respective corresponding resistors.

The RF input 202 is connected to a first drain terminal 266 of the first transistor 206 and is also connected to a first source terminal 264 of the first transistor 206 via a first shunt resistor (Rsh) 226. The first source terminal 264 is also connected to a second drain terminal 270 of the second transistor 208 and to the second source terminal 272 of the second transistor 208 via a second shunt resistor 228. The second source terminal 272 is connected to a third drain terminal 274 of the third transistor 210 and to a third source terminal 276 of the third transistor 210 via a third shunt resistor Rsh 230. The third source terminal 276 is connected to the RF output 204. This arrangement is an example of a series connection of one FDSOI RVT FET with two other FDSOI RVT FETs, wherein the two other FDSOI RVT FETs each comprises a respective N-well receiving to the high N-well bias voltage and a respective P-well connected to the P-well bias voltage.

In operation, a gate voltage is applied to the VGG input 254 to cause the FDSOI RVT FETs to conduct or not conduct between their sources and drains. In an example, a VGG voltage of between 0.8 and 1.0 volts is applied to the VGG input 254 to place the FDSOI RVT FETs into their conductive, or on, state. In some of these examples, the stacked switch circuit arrangement 200 is placed into an off state by applying a VGG voltage to the VGG input 254 of between negative 0.8 and negative 1.0 volts (−0.8 V to −1.0 V)

In addition to changing the VGG voltage to change between the on and off states, different values of bias voltages are applied to the VBG terminal 250 and in some cases to the VBIAS terminal 252 based on whether the FDSOI RVT FETs in the stacked switch circuit arrangement 200 are in an on state or off state. When the stacked switch circuit arrangement is in the on state, high voltages are provided to the VBG terminal 250 and the VBIAS terminal 252.

In some examples, when the stacked switch circuit arrangement 200 is in the on state, high voltages over three volts (3 V) are applied to the VBG terminal 250 and the VBIAS terminal 252. In some such examples, high voltages between three (3) and five (5) volts are applied to the VBG terminal 250 and VBIAS terminal 252 when the stacked switch circuit arrangement 200 is in the on state. The application of such high voltages to the VBG terminal 250, and thus the P-well 106, and to the VBIAS terminal 252, and thus the N-well 104, when the stacked switch circuit arrangement 200 is in the on state contrasts with conventional FDSOI RVT FET circuit designs that generally apply voltages between 1 V and 1.8 V to the P-well 106 and N-well 104 layers of FDSOI FVT FETs when they are configured to conduct.

When the stacked switch circuit arrangement 200 is in an off state, a low voltage, such as in a range between zero volts (0 V) to one volt (1 V), is applied to the VBG terminal 250 when the FDSOI RVT FETs. In some examples, this low voltage or a similar low voltage is also applied to the VBIAS terminal 252 when the stacked switch circuit arrangement 200 is in the off state. In some such examples, the VBIAS terminal, and thus the N-well 104, remains fixed to this higher voltage regardless of the state of the stacked switch circuit arrangement 200 being either on or off. If further examples, a high voltage of, for example, over three (3) volts as is described above as being applied to the VBIAS terminal 252 when the stacked switch circuit arrangement 200 is on the on state, is able to be also applied to the VBIAS terminal 252 while the stacked switch circuit arrangement 200 is in the off state.

It has been found that different values of the high voltages applied to the VBG terminal 250, and thus to the P-well 106, and to the VBIAS terminal 252, and thus to the N-well 104, affect the linearity of the FDSOI RVT FETs when in the on state. Selection of different values of high voltages in some examples allows a trade-off between levels of second harmonics and third harmonics generated by the stacked switch circuit arrangement 200 when in the on state. For example, it has been observed in simulations that setting a high voltage of three volts (3 V) at the VBG terminal 250, and thus the voltage of the P-well, and to also set the same voltage at the VBIAS terminal 252, and thus the voltage of the N-well 104, results in a favorable level of second harmonics and third harmonics when the stacked switch circuit arrangement 200 is in the on state relative to conventional circuit arrangements. Simulations have also shown that increasing the high voltage provided to the VBG terminal 250 and VBIAS terminal 252 to five volts (5 V) provides reduced second harmonic levels relative to a high voltage of 3 V, but with an increase of third harmonic levels relative to a high voltage of 3 V. As such, a design tradeoff between second harmonic levels and third harmonic levels has been observed by varying the high voltages applied to the VBIAS terminal 252, and thus the N-well 104, and the VBG terminal 252, and thus the P-well 106.

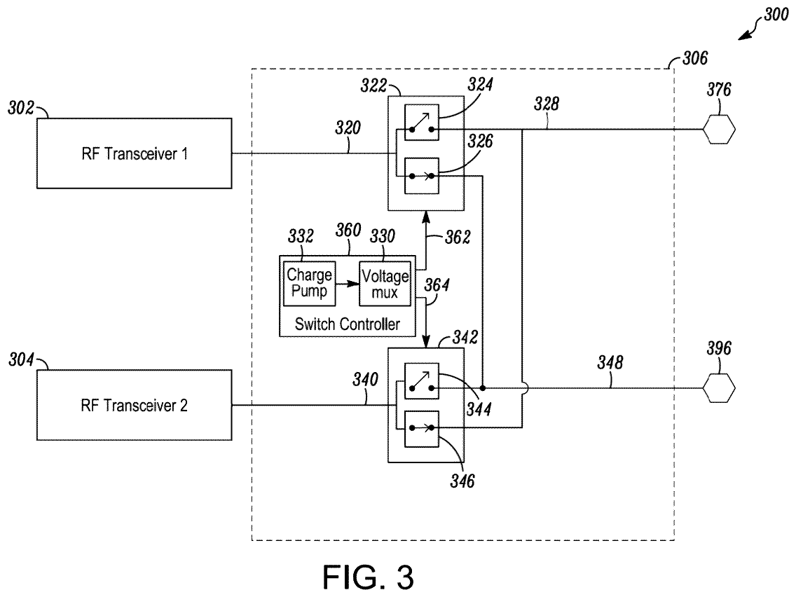

FIG. 3 illustrates a multiplexed RF switching arrangement 300, according to an example. The multiplexed RF switching arrangement 300 depicts an RF multiplexing switch component 306 that selectively connects two RF transceivers, a first RF transceiver 1 302 and a second RF transceiver 2 304, between two RF connections, a first RF connection 376 and a second RF connection 396. In the illustrated example, the RF multiplexing switch component 306 supports bi-directional flow of RF energy between the RF transceivers and the RF connections. In further examples, RF receivers, RF transmitters, or both, are able to be connected to ports of the RF multiplexing switch component 306. The multiplexed RF switching arrangement 300 is an example of a circuit that is able to include FDSOI RVT FETs that operate as described above to achieve beneficial improvements in circuit cost, integration, operational characteristics such as harmonic performance, other benefits, or combinations of these, relative to conventional designs.

The RF multiplexing switch component 306 includes a first RF multiplexing switch 322 and a second RF multiplexing switch 342. Each RF multiplexing switch in an example includes two stacked switch circuits where each such stacked switch circuit has a configuration described above with regards to the stacked switch circuit arrangement 200. In further examples, stacked switch circuits with configurations similar to the stacked switch circuit arrangement 200 are able to be used in any combination with one another in order to create any switching arrangement including, for example, multiplexers to selectively connect any number of ports to one another.

The first RF multiplexer switch 322 is connected to a first RF port 320 to exchange RF energy with the first RF transceiver 1 302. The second RF multiplexer switch 342 is connected to a second RF port 340 to exchange RF energy with the second RF transceiver 2 304. The first RF connection 376 is connected to a third RF port 328. The third RF port 328 is connected to a first stacked switch circuit 324 within the first RF multiplexing switch 322 and to a fourth stacked switch circuit 346 of the second RF multiplexing switch 342. The second RF connection 396 is connected to a fourth RF port 348. The fourth RF port 348 is connected to a second stacked switch circuit 326 within the first RF multiplexing switch 322 and to a third stacked switch circuit 344 of the second RF multiplexing switch 342.

The multiplexed RF switching arrangement 300 includes a switch controller 360 that provides switch control signals to the RF multiplexer switches. The switch controller 360 provides a first set of switch control signals 362 to the first RF multiplexer switch 322 and provides second set of switch control signals 362 to the second RF multiplexer switch 342. The switch controller 360 includes a charge pump 332 and a voltage multiplexer 330 to generate proper switch control voltages for the RF multiplexer switches and direct those switch control voltages to the various stacked switch circuits as is described in further detail below.

In order to simplify the description of the relevant aspects of the presently described systems and methods, the multiplexed RF switching arrangement 300 depicts an RF multiplexing switch component 306 with only two multiplexing switches that each switch one port between two other ports. In general, any number of stacked switch circuits are able to be connected in any arrangement to selectively connect any number of ports to one another according to particular design criteria.

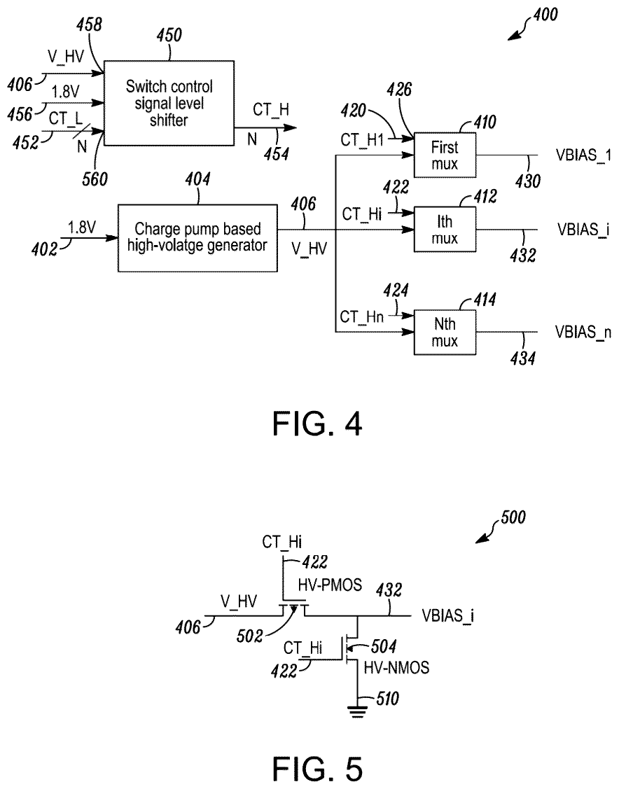

FIG. 4 illustrates a bias voltage multiplexer circuit 400, according to an example. The bias voltage multiplexer circuit 400 is an example of a bias voltage source with a charge pump circuit and depicts circuitry included in the above-described switch controller 360 and the voltage multiplexer 361. The illustrated bias voltage multiplexer circuit 400 depicts a bias voltage multiplexer that is able to selectively provide bias voltages to a number “n” of stacked switch circuits, where each stacked switch circuit is similar to the above described first stacked switch circuit 324 with an arrangement as depicted above for the stacked switch circuit arrangement 200. In the above-described multiplexed RF switching arrangement 300, the bias voltage multiplexer circuit 400 separately and selectively provides bias voltages to each of the four (4) stacked switch circuits of that circuit.

As noted above, the stacked switch circuit arrangement 200 operates by providing high voltage bias signals as bias voltages to transistor well regions. The high voltage provided to the P-well and N-well of these transistors when these transistors are in the on state is higher than voltages normally present in associated circuits. In order provide this higher voltage, the bias voltage multiplexer circuit 400 in an example includes a charge pump based high-voltage generator 404. In the illustrated example, 1.8 V is an existing power supply direct current (DC) voltage for other circuit components so a charge pump based high-voltage generator 404 in the illustrated example receives a 1.8 V input 402. The charge pump based high-voltage generator 404 coverts the 1.8 V input 402, which is an example of a DC voltage, to a high-voltage output V_HV 406 that is an example of a charge pump voltage or an increased voltage that is higher than the DC voltage. The V_HV 406 in some examples is a high N-well bias voltage that is derived from the charge pump voltage and provided to the N-well 104. The V_HV 406 in some examples N-well 104 and P-well 106 are electrically coupled together, the V_HV 406 is a high P-well bias voltage that is provided as a bias voltage to both the P-well 106 and N-well 104 of triple well transistors in the stacked switch circuit arrangement 200.

The high voltage output V_HV 406 is provided to n voltage multiplexers (MUXs) where “n” corresponds to the number of stacked switch circuits being controlled. The bias voltage multiplexer circuit 400 shows a first MUX 410, an ith MUX 412, and an nth MUX 414. Each MUX in the illustrated example selectably provides a bias voltage to the triple well transistors of each stacked switch circuit where that bias voltage is switched between the voltage of the high voltage output V_HV 406 and a lower voltage, such as ground, based on whether the triple well transistors in that stacked switch circuit are in their on or off state.

In order to facilitate switching of the V_HV 406 by the MUXs, the bias voltage multiplexer circuit 400 includes a switch control signal level shifter 450. The switch control signal level shifter 450 in an example includes a switch control input 560 that receives a set of lower voltage switch control signals CT_L signals 452 that contains N switch control signals that has a separate switch control signal for each MUX that alternately indicates whether that stacked switched circuit to be in either an on or off condition. The switch control signal level shifter 450 communicatively couples the bias voltage multiplexer circuit 400 to the switch control input 560 and operates to convert the lower voltage switch control signals CT_L signals 452 to higher voltage switch control signals that are able to effectively drive switching transistors in each MUX. In an example, the CT_L signals 452 contain one CT_L signal for each MUX and thus each stacked switch circuit. The CT_L signals 452 in an example switch between zero volts (0 V) for an off state and 1.8 V for an on state. In further examples, other voltage levels are able to be used. An example of a switching transistor arrangement for each MUX is described in further detail below.

The switch control signal level shifter 450 has a 1.8 V input 456 and a high voltage input 458 to receive the high voltage V_HV 406 produced by the charge pump based high-voltage generator 404. The switch control signal level shifter 450 operates to produce high voltage switch control signals CT_H outputs 454 by converting each CT_L signal in the CT_L signals 452 to signals that switch between a suitable off voltage for the mux, which results from the CT_L signal being in the off condition, to a high voltage level that is based on the V_HV 406 when the CT_L signal is in the on condition. The switch control signal level shifter 450 produces a set of CT_H outputs 454 that has one CT_H output for each MUX. In the illustrated example, the CT_H outputs 454 include a CT_H1 switch control signal 420 to control the first MUX 410 that produces a VBIAS_1 430 as a bias voltage for the triple well transistors of a first stacked switch circuit. The CT_H1 switch control signal 420 is received by the first MUX 410 at a first switch control input 426. In the illustrated example, the P-well and N-well of the triple well transistors of each stacked switch circuit are provided with equal bias voltages that change based on the on or off state of that stacked switch circuit. The CT_H outputs 454 also include a CT_Hi switch control signal 422 to control an ith MUX 412 that produces a VBIAS_i 432 as a bias voltage for the triple well transistors of an ith stacked switch circuit, and an CT_Hn switch control signal 424 to control the nth MUX 414 that produces a VBIAS_n 434 as a bias voltage for the triple well transistors of an nth stacked switch circuit. Each of these MUXs receives its switch control signal at a respective switch control input. These received switch control signals alternatingly indicate an on state or an off state for the stacked switch circuit to which the receiving MUX provides bias voltages.

FIG. 5 illustrates an ith bias voltage multiplexer circuit 500, according to an example. The depicted ith bias voltage multiplexer circuit 500 is an example of a circuit to implement each of the above-described MUX elements of the bias voltage multiplexer circuit 400, such as the ith MUX 412.

The ith bias voltage multiplexer circuit 500 receives the V_HV 406 to be selectively provided to as a bias voltage to the triple well transistors of an associated stacked switch circuit. The V_HV 406 is switched by a first High Voltage P-channel Metal-Oxide Semiconductor (HV-PMOS) transistor 502, which is an example of a high voltage switching transistor, to connect, based on the CT_Hi signal indicating an on state, a high-level voltage as an VBIAS_i output 432. This high-level voltage is an example of a high P-well bias voltage and, in an arrangement where the P-well 106 and the N-well 104 are electrically coupled, is also an example of a high N-well bias voltage. In order to properly control the gate voltage of the first HV-PMOS transistor 502, the CT_Hi switch control signal 420 as generated by the above-described switch control signal level shifter 450 is provided as a gate voltage to the first HV-PMOS transistor 502. The VBIAS_i output 432 is also selectively switched to a low voltage, such as ground in the illustrated example, by a High Voltage N-channel Metal-Oxide Semiconductor (HV-NMOS) transistor 504, which is an example of a low voltage switching transistor, to connect, based on the CT_Hi signal indicating an off state, a low-level voltage as an VBIAS_i output 432. This low-level voltage is an example of a low P-well bias voltage and, in an arrangement where the P-well 106 and the N-well 104 are electrically coupled, is also an example of a low N-well bias voltage.

As noted above, the CT_Hi switch control signal switches between the V_HV 406 level and a lower level to command the VBIAS_i output 432 to a high or low level corresponding to the on or off state of the stacked switched circuit containing the triple well transistors receiving the VBIAS_i output 432. The complementary design of the first HV-PMOS transistor 502 and the HV-NMOS transistor 504 causes the VBIAS_i output 432 to switch between the voltage level of the V_HV or a low voltage level, such as ground, based on the level of the CT_Hi switch control signal 422.

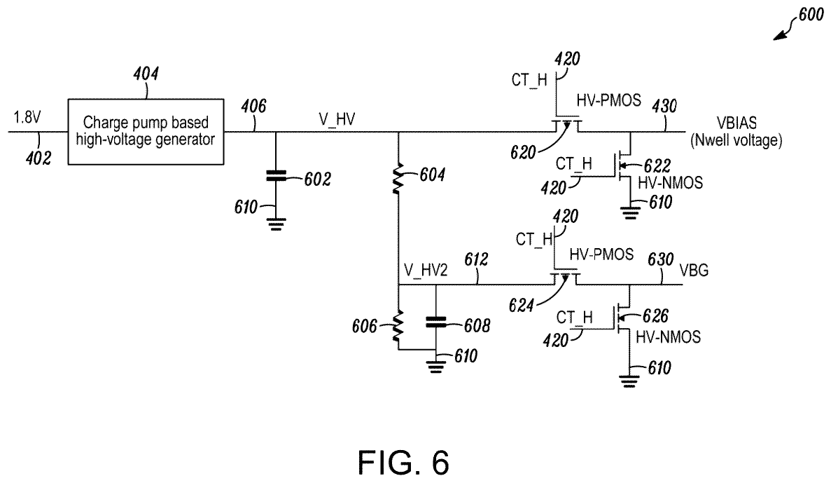

FIG. 6 illustrates a dual bias voltage multiplexer 600, according to an example. As noted above with regards to the FDSOI RVT FET cross section 100, the P-well 106 and N-well 104 of a triple well transistor in the above-described stacked switch circuit arrangement 200 are each able to have different bias voltages. As noted with the stacked switch circuit arrangement 200, the N-well 104 is provided with a VBIAS terminal 252 and the P-well 106, which is referred to as a back gate, is provided Back Gate Voltage VBG terminal 250.

The dual bias voltage multiplexer 600 operates to provide separate VBIAS output 430 and a VBG output 630 to be provided to the VBIAS terminal 252 and the VBG terminal 250 of the stacked switch circuit arrangement 200. As described above with regards to the ith bias voltage multiplexer circuit 500, the dual bias voltage multiplexer 600 depicts the charge pump based high-voltage generator 404 as described above with regards to the bias voltage multiplexer circuit 400, that produces a V_HV 406 as a charge pump voltage than is higher than a DC voltage provided to the charge pump based high-voltage generator 404, i.e., the 1.8 V input 402 in the illustrated example. The VBIAS output 430, which is provided to the N-well 104, is switched between the V_HV 406 and a ground level 610 in the illustrated example by a VBIAS HV-PMOS transistor 620 and a VBIAS HV-NMOS transistor 622 based on the CT_H switch control signal 420 being in either the on state or off state respectively.

The illustrated dual bias voltage multiplexer 600 creates a V_HV2 voltage 612 that is a voltage level to be applied to the P-well 106, or back gate, of each triple well transistor when its stacked switch circuit is in the on state. The dual bias voltage multiplexer 600 generates the V_HV2 voltage 612 by deriving the V_HV2 voltage 612, that is provided to the P-well 106, from the voltage provided by the charge pump based high-voltage generator 404, i.e., V_HV 406, by reducing V_HV 406 with a voltage divider formed by a first resistor 604 and a second resistor 606. The V_HV2 voltage 612 is filtered by a V_HV2 capacitor 608 and provided to a source of a VBG HV-PMOS transistor 624 that is switched to a VBG output 630 to provide the V_HV2 voltage 612 to the P-well 106 via the VBG terminal 250 based on the level of the CT_H signal 420 indicating an on state. The VBG HV-PMOS transistor 624 is an example of a P-well bias high voltage switching transistor. A ground voltage level is provided to the P-well 106 by also being switched to the VBG output 630 based on the CT_H switch control signal 420 indicating an off state where the CT_H switch control signal 420 drives the gate of a VBG HV-NMOS transistor 622, which is an example of a P-well bias low voltage switching transistor. The control of the VBG HV-PMOS transistor 624 and the VBG HV-NMOS transistor 626 is similar to the above-mentioned control of the VBIAS HV-PMOS transistor 620 and the VBIAS HV-NMOS transistor 622.

Some features of the present invention may be used in an embodiment thereof without use of other features of the present invention. As such, the foregoing description should be considered as merely illustrative of the principles, teachings, examples, and exemplary embodiments of the present invention, and not a limitation thereof.

These embodiments are only examples of the many advantageous uses of the innovative teachings herein. In general, statements made in the specification of the present application do not necessarily limit any of the various claimed inventions. Moreover, some statements may apply to some inventive features but not to others.

The circuit as described above is part of a design of an IC. The design of the IC is created in a graphical computer programming language, and stored in a computer storage medium (such as a disk, tape, physical hard drive, or virtual hard drive such as in a storage access network). If a designer does not fabricate chips or photolithographic masks used to fabricate chips, the designer transmits the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

The methods as discussed above are used in fabrication of ICs. The resulting ICs can be distributed by the fabricator in raw wafer form (that is, as a single wafer that has multiple unpackaged chips), as a bare chip, or in a packaged form. In the latter case, the IC is mounted in a single chip package or in a multichip package. In any case, the IC is then coupled to other ICs, discrete circuit elements, and/or other signal processing devices as part of either (a) an intermediate product, such as a motherboard, or (b) an end product. The end product can be any product that includes ICs, ranging from toys and other low-end applications to advanced computer products (such as, but not limited to, an information processing system) having a display, a keyboard, or other input device, and a central processor.

Unless stated otherwise, terms such as “first” and “second” are used to arbitrarily distinguish between the elements that such terms describe. Thus, these terms are not necessarily intended to indicate temporal or other prioritization of such elements.

The terms “a” or “an”, as used herein, are defined as one as or more than one. The term plurality, as used herein, is defined as two as or more than two. Plural and singular terms are the same unless expressly stated otherwise. The term another, as used herein, is defined as at least a second or more. The terms including and/or having, as used herein, are defined as comprising (i.e., open language). The term coupled, as used herein, is defined as connected, although not necessarily directly, and not necessarily mechanically. The terms program, software application, and the like as used herein, are defined as a sequence of instructions designed for execution on a computer system. A program, computer program, or software application may include a subroutine, a function, a procedure, an object method, an object implementation, an executable application, an applet, a servlet, a source code, an object code, a shared library/dynamic load library and/or other sequence of instructions designed for execution on a computer system.

Although specific embodiments of the invention have been disclosed, those having ordinary skill in the art will understand that changes can be made to the specific embodiments without departing from the spirit and scope of the invention. The scope of the invention is not to be restricted, therefore, to the specific embodiments, and it is intended that the appended claims cover any and all such applications, modifications, and embodiments within the scope of the present invention.

What is claimed is:

1. A radio frequency switching transistor circuit, comprising:
a Fully Depleted Silicon on Insulator (FDSOI) Regular Threshold Voltage (RVT) Field Effect Transistor (FET);
a switch control input configured to receive, when operating, a switch control signal alternatingly indicating an on state and an off state; and
a bias voltage source, communicatively coupled to the switch control input, the bias voltage source generating a P-well bias voltage and a high N-well bias voltage, wherein the bias voltage source is:
coupled to and provides the P-well bias voltage to a P-doped well (P-well) of the FDSOI RVT FET, and
coupled to and provides the high N-well bias voltage to an N-doped well (N-well) of the FDSOI RVT FET,
wherein the P-well bias voltage comprises:
based on the switch control signal indicating an on state, a high P-well bias voltage that is higher than supply voltages for any of a source, a gate, or a drain of the FDSOI RVT FET, and
based on the switch control signal indicating an off state, a low P-well bias voltage lower than the high P-well bias voltage and that facilitates the FDSOI RVT FET switching to an off state, and
wherein the high N-well bias voltage is equal to or higher than the high P-well bias voltage.

2. The radio frequency switching transistor circuit of claim 1, wherein the high N-well bias voltage is provided based on the switch control signal indicating the on state, and wherein the bias voltage source is further configured to, when operating, generate and provide a low N-well bias voltage based on the switch control signal indicating the off state, wherein the low N-well bias voltage is lower than the high N-well bias voltage.

3. The radio frequency switching transistor circuit of claim 1, wherein the high P-well bias voltage is equal to the high N-well bias voltage.

4. The radio frequency switching transistor circuit of claim 1, wherein the high P-well bias voltage is greater than either a core voltage or an I/O voltage of the FDSOI RVT FET.

5. The radio frequency switching transistor circuit of claim 1, wherein the high N-well bias voltage is provided when the switch control signal indicates either the on state and the off state.

6. The radio frequency switching transistor circuit of claim 1, further comprising a series connection of the FDSOI RVT FET with two other FDSOI RVT FETs, wherein the two other FDSOI RVT FETs each comprises a respective N-well receiving to the high N-well bias voltage and a respective P-well connected to the P-well bias voltage.

7. The radio frequency switching transistor circuit of claim 1, wherein the bias voltage source comprises a charge pump circuit to convert a DC voltage to a charge pump voltage higher than the DC voltage and wherein the high P-well bias voltage is derived from the charge pump voltage, wherein the radio frequency switching transistor circuit further comprises:
a P-well bias high voltage switching transistor to provide, based on the switch control signal indicating the on state, a voltage derived from and lower than the charge pump voltage to the P-well; and
a P-well bias low voltage switching transistor to provide, based on the switch control signal indicating the off state, the low P-well bias voltage to the P-well.

8. The radio frequency switching transistor circuit of claim 1, wherein the bias voltage source comprises a charge pump circuit to convert a DC voltage to a charge pump voltage higher than the DC voltage and wherein the high P-well bias voltage and the high N-well bias voltage are derived from the charge pump voltage.

9. The radio frequency switching transistor circuit of claim 8, wherein the bias voltage source further comprises:
a high voltage switching transistor to connect, based on the switch control signal indicating the on state, the charge pump voltage to the P-well; and
a low voltage switching transistor to connect, based on the switch control signal indicating the off state, the P-well to the low P-well bias voltage.

10. The radio frequency switching transistor circuit of claim 9, wherein the P-well is electrically coupled to the N-well.

11. A method of controlling an on off state of a radio frequency switching transistor circuit, the method comprising:
receiving a switch control signal alternatingly switching between an on state and an off state;
generating an N-well bias voltage comprising a high N-well bias voltage that is higher than supply voltages provided to any of a source, a gate, or a drain of a FDSOI RVT FET;
providing the high N-well bias voltage to an N-well of the FDSOI RVT FET;
generating a P-well bias voltage comprising, based on a state of the switch control signal, a high P-well bias voltage that is higher than the supply voltages, and a low P-well bias voltage lower than the high P-well bias voltage and facilitates the FDSOI RVT FET switching to an off state;
providing, based on the switch control signal indicating the on state, the high P-well bias voltage to a P-well of the FDSOI RVT FET; and
providing, based on the switch control signal indicating the off state, the low P-well bias voltage to the P-well of the FDSOI RVT FET.

12. The method of claim 11, wherein the high N-well bias voltage is provided based on the switch control signal indicating the on state,
wherein the high N-well bias voltage is generated based on the switch control signal indicating the on state, and wherein generating the N-well bias voltage further comprises generating, based on the switch control signal indicating the off state, a low N-well bias voltage lower than the high N-well bias voltage, and
the method further comprising:
providing, based on the switch control signal indicating the on state, the high N-well bias voltage to the N-well of the FDSOI RVT FET; and
providing, based on the switch control signal indicating the off state, the low N-well bias voltage to the N-well of the FDSOI RVT FET.

13. The method of claim 11, wherein the high P-well bias voltage is equal to the high N-well bias voltage.

14. The method of claim 11, wherein the high P-well bias voltage is greater than either a core voltage or an I/O voltage of the FDSOI RVT FET.

15. The method of claim 11, wherein the high N-well bias voltage is provided when the switch control signal indicates either the on state and the off state.

16. The method of claim 11, further comprising:
converting a DC voltage to an increased voltage higher than the DC voltage; and
deriving the high N-well bias voltage from the increased voltage, and wherein
providing the high P-well bias voltage comprises switching, with a P-well bias high voltage switching transistor, a voltage derived from the increased voltage and that is lower than the increased voltage to connect, based on the switch control signal indicating the on state, the P-well to the voltage derived from the increased voltage, and wherein
providing the low P-well bias voltage comprises switching a P-well bias low voltage switching transistor to connect, based on the switch control signal indicating the off state, the P-well to the low P-well bias voltage.

17. The method of claim 11, further comprising:
converting a DC voltage to an increased voltage higher than the DC voltage; and
deriving the high P-well bias voltage and the high N-well bias voltage from the increased voltage.

18. The method of claim 17, wherein
providing the high P-well bias voltage comprises switching an increased voltage switching transistor to connect, based on the switch control signal indicating the on state, the P-well to the increased voltage, and wherein
providing the low P-well bias voltage comprises switching a low voltage switching transistor to connect, based on the switch control signal indicating the off state, the P-well to a low P-well bias voltage.

19. The method of claim 18, wherein the P-well is electrically coupled to the N-well.

20. A radio frequency switching transistor circuit, comprising:
a Fully Depleted Silicon on Insulator (FDSOI) Regular Threshold Voltage (RVT) Field Effect Transistor (FET);
a switch control input configured to receive, when operating, a switch control signal alternatingly indicating an on state and an off state;
a charge pump circuit to convert a DC voltage to a charge pump voltage higher than the DC voltage and wherein a high P-well bias voltage that is higher than supply voltages for any of a source, a gate, or a drain of the FDSOI RVT FET and a high N-well bias voltage are derived from the charge pump voltage;
a high voltage switching transistor to connect, based on the switch control signal indicating the on state, the charge pump voltage to a P-doped well (P-well) of the FDSOI RVT FET; and
a low voltage switching transistor to connect, based on the switch control signal indicating the off state, the P-well to a low P-well bias voltage that is lower than the high P-well bias voltage and that facilitates the FDSOI RVT FET switching to an off state,
wherein an N-doped well (N-well) of the FDSOI RVT FET receives the high N-well bias voltage, and
wherein the high N-well bias voltage is equal to or higher than the high P-well bias voltage.
